(19) United States
(12) Patent Application Publication
(10) Pub. No.: US 2026/0211772 A1
(43) Pub. Date: Jul. 23, 2026

(54) IN-MEMORY REPAIR INFORMATION FOR A ROW SUBSET

(71) Applicant: QUALCOMM Incorporated, San Diego, CA (US)

(72) Inventors: Wonhyung Song, Osan-si (KR); Jungwon Suh, San Diego, CA (US)

(21) Appl. No.: 19/032,615

(22) Filed: Jan. 21, 2025

(51) Int. Cl. G06F 11/10

(52) U.S. Cl. CPC G06F 11/1076

(57) ABSTRACT

A memory device includes control circuitry configured to receive, from a memory controller, a write request to write data to a memory array. The data is associated with an address of the memory array, and the address corresponds to a row of storage elements of the memory array. The control circuitry is further configured to generate repair information associated with the data based on the row of storage elements including one or more storage elements associated with a defect. The repair information includes a copy of a particular subset of the data corresponding to a portion of the row of storage elements, and the portion of the row of storage elements includes the one or more storage elements associated with the defect. The control circuitry is further configured to store the data to the row of storage elements and to store the repair information to the memory array.

### TECHNICAL FIELD

Aspects of the present disclosure relate generally to memory devices, and more particularly, to repair of data errors that may be associated with memory devices.

### INTRODUCTION

Electronic devices increasingly perform a variety of functions for users. For example, in addition to supporting voice calls, a mobile device (such as a smart phone) may support a variety of other operations and may include a variety of electronic components to support these operations. The operations may include, for example, image and video capture, health monitoring and activity tracking, wireless local area network (WLAN) communications, personal area network (PAN) communications, satellite communications, and other features. As another example, a vehicle may support wireless communications, navigation, and other driver assistance features such as adaptive cruise control, lane change assistance, collision avoidance, night vision, parking assistance, blind spot detection, lane keeping assistance, automated braking, partially autonomous driving, and fully autonomous driving.

To facilitate such a wide range of operations, memory devices are used to enable storage and retrieval of data. One example of a memory device is a dynamic random access memory (DRAM) device. A DRAM device may include volatile storage elements that facilitate relatively fast storage and retrieval of data. For example, in some systems, an integrated circuit may include one or more processors that store data to, and retrieve data from, a DRAM device that is coupled to the integrated circuit.

As electronic devices increasingly generate, store, and process large amounts of data, memory devices may be increasingly important to device performance. In some cases, memory devices may be subject to defects, such as shorted or “broken” wires or storage elements. Such defects may occur during device manufacturing, during packaging or product assembly, or during end user operation, as illustrative examples. Some conventional mechanisms to address such defects may be relatively expensive or complex. For example, some on-die error correction code (ECC) techniques may involve relatively complex circuitry and may occupy die area of a memory device. Further, in some cases, ECC techniques and other techniques may be insufficient to correct data errors. In some circumstances, if the error correction capability of an ECC technique is exceeded, use of the ECC technique may increase a quantity of errors in data.

### BRIEF SUMMARY OF SOME EXAMPLES

The systems, methods and devices of this disclosure each have several innovative aspects, no single one of which is solely responsible for the desirable attributes disclosed herein.

In some aspects, a memory device includes a memory array and control circuitry coupled to the memory array. The control circuitry is configured to receive, from a memory controller, a write request to write data to the memory array. The data is associated with an address of the memory array, and the address corresponds to a row of storage elements of the memory array. The control circuitry is further configured to generate repair information associated with the data based on the row of storage elements including one or more storage elements associated with a defect. The repair information includes a copy of a particular subset of the data corresponding to a portion of the row of storage elements, and the portion of the row of storage elements includes the one or more storage elements associated with the defect. The control circuitry is further configured to store the data to the row of storage elements and to store the repair information to the memory array.

In some further aspects, a method of operation of a memory device includes receiving, from a memory controller, a write request to write data to the memory device. The data is associated with an address of the memory device, and the address corresponds to a row of storage elements of the memory device. The method further includes generating repair information associated with the data based on the row of storage elements including one or more storage elements associated with a defect. The repair information includes a copy of a particular subset of the data corresponding to a portion of the row of storage elements, and the portion of the row of storage elements includes the one or more storage elements associated with the defect. The method further includes storing the data to the row of storage elements and storing the repair information to the memory device.

In some additional aspects, a non-transitory computer-readable medium stores instructions executable by one or more processors of a memory device to initiate, perform, or control operations. The operations include receiving, from a memory controller, a write request to write data to the memory device. The data is associated with an address of the memory device, and the address corresponds to a row of storage elements of the memory device. The operations further include, based on the row of storage elements including one or more storage elements associated with a defect, generating repair information associated with the data. The repair information includes a copy of a particular subset of the data corresponding to a portion of the row of storage elements, and the portion of the row of storage elements includes the one or more storage elements associated with the defect. The operations further include storing the data to the row of storage elements and storing the repair information to the memory device.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

FIG. 1 illustrates an example of a system that supports in-memory repair information for a row subset.

FIG. 2 illustrates an example of a system that supports in-memory repair information for a row subset.

FIG. 3 illustrates an example of a memory device that supports in-memory repair information for data subsets.

FIG. 4 illustrates examples of features that may be associated with repair information for in-memory repair information for data subsets.

FIG. 5 illustrates an example of a repair scheme that supports in-memory repair information for data subsets.

FIG. 6 illustrates examples of features that may be associated with repair information and data for in-memory repair information for data subsets.

FIG. 7 illustrates examples of a read process and a write process that support in-memory repair information for data subsets.

FIG. 8 illustrates an example of an in-field soft repair process for in-memory repair information for data subsets.

FIG. 9 illustrates example operations that support in-memory repair information for data subsets.

FIG. 10 illustrates an example of a process that supports in-memory repair information for data subsets.

Like reference numbers and designations in the various drawings indicate like elements.

### DETAILED DESCRIPTION

In some aspects of the disclosure, a memory device may use repair information to correct at least one error associated with a defective or unreliable storage element of the memory device. In some examples, data (such as a logical page) may be divided into multiple data subsets. If one of the data subsets is to be stored to a row including the defective or unreliable storage element, the memory device may generate a copy of the data subset and may store the copy to another group of storage elements of the memory device. The copy may be referred to herein as repair bits.

In some implementations, the repair information may include the repair bits and may further include a tag including one or more of a valid bit, an identification tag, or a location tag. A value of the valid bit may indicate whether the repair information is valid (e.g., is to be used during a read operation). The identification tag may indicate a particular prefetch data unit among multiple prefetch data units that is to be associated with the repair information. In some other implementations, each of the multiple prefetch data units may be associated with respective repair information, and the identification tag may be omitted from the repair information. The location tag may indicate a location of the data subset that is to be replaced with the repair bits (e.g., by indicating a particular group of storage elements of the row storing the data).

During a read process associated with the data, the memory device may determine, based on the tag, whether to use the repair bits to repair the data. Based on a determination to repair the data, the memory device may “swap out” the subset of the data with the repair bits (e.g., to correct an error in the data attributable to the defective or unreliable storage element). In some other examples, if the memory device determines that no repair is to be performed, the memory device may output the data (e.g., to a host device or to a memory controller) without repairing the data.

One or more features described herein may improve performance or reduce cost associated with a memory device. To illustrate, a conventional row or column replace scheme may need to devote an entire spare row or column to correct a relatively small quantity of defective storage elements (e.g., a single defective storage element of a row), which may be inefficient. By using repair information as described herein, a more “fine grain” approach may be used to correct a relatively small quantity of defective storage elements and may more closely match a quantity of replacement storage elements to defective storage elements. In addition, in some scenarios, the repair information may be used as an auxiliary (or “fine grain”) repair scheme in addition to a primary repair scheme of the memory device, such as one or more of an error correction code (ECC) scheme or a row or column repair scheme. In this example, the repair information may be selectively generated based on a quantity of errors associated with the row exceeding an error correction capability of the ECC scheme, based on a quantity of defective rows (or columns) of the memory device exceeding a quantity of spare rows (or columns) of the memory device, or both. Further, use of the repair information may enable a reduced quantity of spare rows of columns, which may occupy die area and increase device cost. As a result, data loss associated with errors in data may be reduced or avoided while also decreasing cost and die size overhead of a memory device.

Further, in some implementations, an in-memory repair scheme using repair information as described herein may improve performance as compared to some other techniques, such as in-memory ECC scheme that involves performing error correction on a memory die. In some devices, in-memory ECC schemes may correct errors in data that occur due to physical defects while “hiding” the existence of such physical defects from other devices or components, such as a host device. As a result, the host device may be unable to perform remedial operations associated with the physical defects, such as quarantining a memory area containing a physical defect. Further, some in-memory ECC schemes may involve a significant additional quantity of bits for error-correcting information (e.g., parity bits), which may be unused or wasted if a quantity of errors in data exceeds an error correcting capability of the particular ECC scheme (e.g., in the case of multiple errors with a single-error correction code). Additionally, in-memory ECC schemes may be less robust or effective than other ECC schemes (such as ECC schemes implemented at a memory controller or at a host) and may in some cases generate additional errors if physical defects cause the quantity of errors in data to exceed the error correcting capability of the particular ECC scheme. As a result, use of an in-memory repair scheme may reduce or avoid the need for in-memory ECC schemes to correct errors in data, improving performance and reducing cost and die size overhead of a memory device.

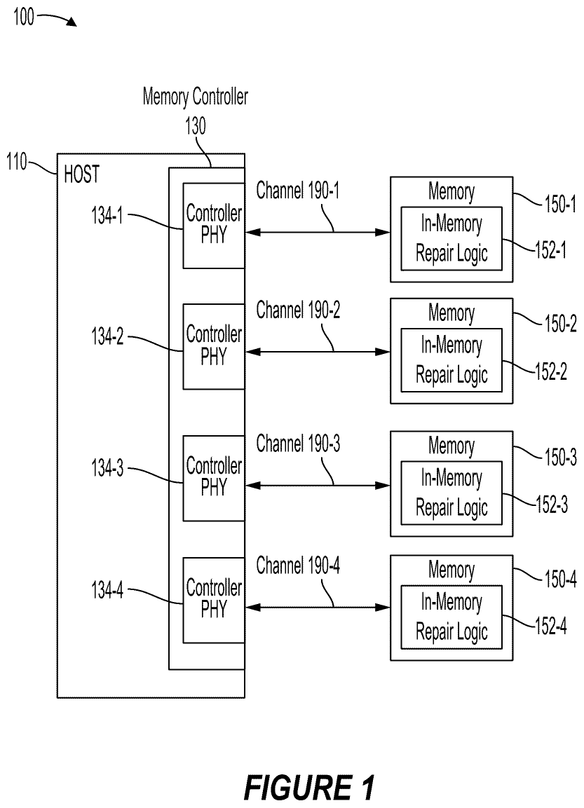

FIG. 1 illustrates an example of a system 100 that supports in-memory repair information for a row subset. The system 100 may include a host 110, memories 150, and channels 190 coupling the host 110 and the memories 150. The system 100 may be, for example, a device a computing system (e.g., a server, a datacenter, or a desktop computer), a mobile computing device (e.g., a laptop or a cellular phone), an Internet of Things (IoT) device, a virtual reality (VR) system, an augmented reality (AR) system, an automobile system (e.g., a driver assistance system or an autonomous driving system), an image capture device (e.g., a stand-alone digital camera, a digital video camera, a camera-equipped wireless communication device, a multimedia system (e.g., a television, a disc player, or a streaming device), or another device.

The host 110 may include at least one processor, such as central processing unit (CPU), graphic processing unit (GPU), digital signal processor (DSP), multimedia engine, and/or neural processing unit (NPU). The host 110 may be configured to couple and to communicate to the memories 150 (e.g., memories 150-1 to 150-4), via channels 190 (e.g., channels 190-1 to 190-4), in performing the computing functions, such as one of data processing, data communication, graphic display, camera, AR or VR rendering, image processing, neural processing, etc. For example, the memories 150-1 to 150-4 may store instructions or data for the host to perform the computing functions.

The host 110 may include a memory controller 130, which may include controller PHY modules 134-1 to 134-4. Each of the controller PHY modules 134-1 to 134-4 may be coupled to a respective one of the memories 150-1 to 150-4 via respective channels 190-1 to 190-4. For ease of reference, read and write are referenced from a perspective of the host 110. For example, in a read operation, the host 110 may receive via one or more of the channels 190-1-190-4 data stored from one or more of the memories 150-1 to 150-4. In a write operation, the host 110 may provide via one or more of the channels 190-1-190-4 data to be written into one or more of the memories 150-1-150-4 for storage. The memory controller 130 may be configured to control various aspects, such as logic layers, of communications to and from the memories 150-1-150-4. The controller PHY modules 134-1-134-4 may be configured to control electrical characteristics (e.g., voltage levels, phase, delays, frequencies, etc.) of signals provided or received on the channels 190-1-190-4, respectively.

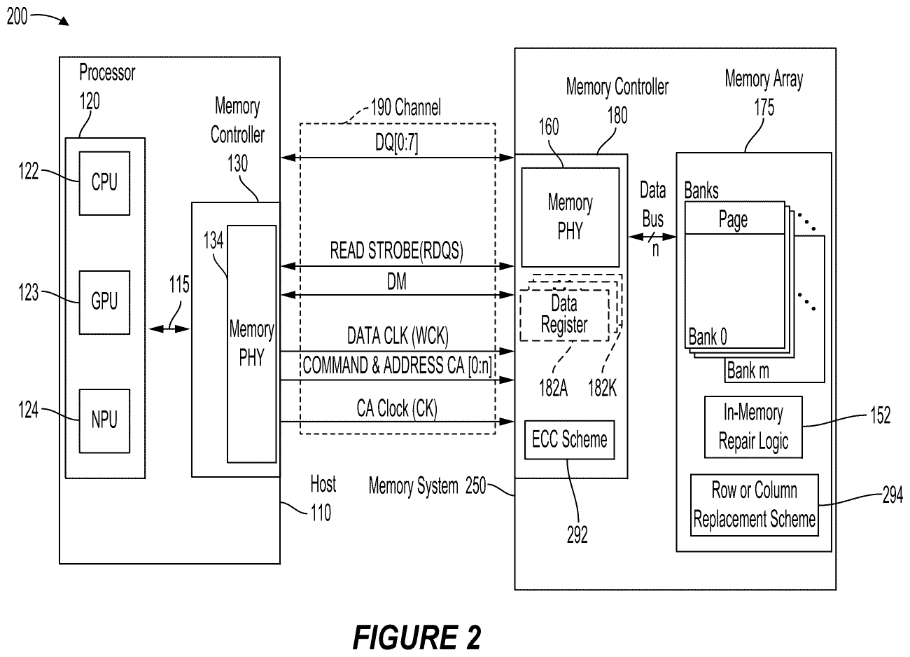

In some examples, the memories 150-1-150-4 may be LPDDR DRAM (e.g., LPDDR5, LPDDR6, or another type of LPDDR DRAM). In some examples, the memories 150-1-150-4 may include different kinds of memory, such as one LPDDR5, one LPDDR6, one flash memory, and one SRAM, respectively. The host 110, the memories 150-1-150-4, and/or the channels 190-1-190-4 may operate according to an LPDDR specification (e.g., an LPDDR5 specification, an LPDDR6 specification, or another type of LPDDR specification). In some examples, each of the channels 190-1-190-4 may include 16 bits of data (e.g., 16 DQs). In some examples, each of the channels 190-1-190-4 may operate on 32 bits of data (e.g., 32 DQs). In FIG. 1, four channels are shown, however the system 100 may include more than four channels or fewer than four channels, such as 8 or 16 channels. Additional features of an example of the system 100 for providing access to a memory system (such as one of memories 150-1-150-4 including logic and a control circuit) are shown in FIG. 2.

FIG. 2 illustrates an example of a system 200 that supports in-memory repair information for data subsets. The system 200 may include the host 110, a memory system 250, and the channel 190 of FIG. 1. The channel 190 between host 110 and the memory system 250 may include a plurality of connections, some of which carry data (e.g., user data or application data) and some of which carry non-data (e.g., addresses and other signaling information). For example, non-data connections in channel 190 may include a data clock (e.g., WCK) used in providing data to the respective memory system 250 and a read data strobe (e.g., RDQS) used in receiving data from the respective memory system 250, on a per byte basis. The channel 190 may further include a data mask (e.g., DM, sometimes referred to as data mask inversion DMI to indicate multiple functions performed by the signal connection) signaling used to mask certain part of data in a write operation. The channel 190 may further include command and address (e.g., CA[0: n]) and associated CA clock to provide commands (e.g., read or write commands) to the memory system 250.

The host 110 may include at least one processor 120, which may include a CPU 122, a GPU 123, and/or an NPU 124. The host 110 may further include a memory controller 130 having a controller PHY module 134. The memory controller 130 may couple to the at least one processor 120 via a bus system 115 in performing the various computing functions. The term “bus system” may provide that elements coupled to the “bus system” may exchange information therebetween, directly or indirectly. In different embodiments, the “bus system” may encompass multiple physical connections as well as intervening stages such as buffers, latches, registers, etc. A module may be implemented in hardware, software, or a combination of hardware and software.

The memory controller 130 may send and/or receive blocks of data to other modules, such as the at least one processor 120 and/or the memory system 250. The memory system 250 may include a memory controller 180 with a memory I/O module 160 (e.g., a PHY layer) configured to control electrical characteristics (e.g., voltage levels, phase, delays, frequencies, etc.) to provide or to receive signals on connections of the channel 190. For example, memory I/O module 160 may be configured to capture (e.g., to sample) data, commands, and addresses from the host 110 via the channel 190 and to output data to the host 110 via the channel 190. The memory controller 180 may also include data registers 182A-K configured to store data in transit between the host 110 and the memory array 175 and/or to store configuration settings or other data.

The memory system 250 may further include a memory array 175, which may include multiple memory cells (e.g., DRAM memory cells, MRAM memory cells, SRAM memory cells, Flash memory cells) that store values. The host 110 may read data stored in the memory array 175 and write data into the memory array 175, via the channel 190 and the memory I/O module 160. The memory array 175 may be divided into a plurality of banks with each bank organized as a plurality of pages.

Application or user data may be processed by the processor 120 and the memory controller 130 instructed to store and/or retrieve such data from the memory system 250. For example, data may be generated during the execution of an application, such as a spreadsheet program that computes values based on other data. As another example, data may be generated during the execution of an application by receiving user input to, for example, a spreadsheet program. As a further example, data may be generated during the execution of a gaming application, which generates information regarding a representation of a scene rendered by a three-dimensional (3-D) application.

The host 110 is coupled to the memory system 250 via the channel 190, which is illustrated for a byte of data, DQ[0:7]. The channel 190 and signaling between the host 110 and the memory system 250 may be implemented in accordance with the JEDEC DRAM specification (e.g., LPDDR5, LPDDR6). As illustrated, the channel 190 includes signal connections of the DQs, a read data strobe (RDQS), a data mask (DM), a data clock (WCK), command and address (CA[0: n]), and command and address clock (CK). The host 110 may use the read data strobe RDQS to strobe (e.g., to clock) data in a read operation to receive the data on the DQs. The memory system 250 may use the data mask DM to mask certain parts of the data from being written in a write operation. The memory system 250 may use the data clock WCK to sample data on the DQs for a write operation. The memory system 250 may use the command and address clock CK to clock (e.g., to receive) the CAs. A signal connection for each of the signaling may include a pin at the host 110, a pin at the memory system 250, and a conductive trace or traces electrically connecting the pins. The conductive trace or traces may be part of a single integrated circuit (IC) on a silicon chip containing the processor 120 and the memory system 250, may be part of a package on package (PoP) containing the processor 120 and the memory system 250, or may be part of a printed circuit board (PCB) coupled to both the processor 120 and the memory system 250.

The memory system 250 may include a memory I/O module 160 (e.g., a PHY layer) configured to control electrical characteristics (e.g., voltage levels, phase, delays, frequencies, etc.) to provide or to receive signals on the channel 190. For example, memory I/O module 160 may be configured to capture (e.g., to sample) data, commands, and addresses from the host 110 via the channel 190 and to output data to the host 110 via the channel 190. Information transmitted across the channel 190 may be stored in registers in the memory I/O module 160 of the memory system 250 as a temporary or short-term storage location prior to longer-term storage in the memory array 175.

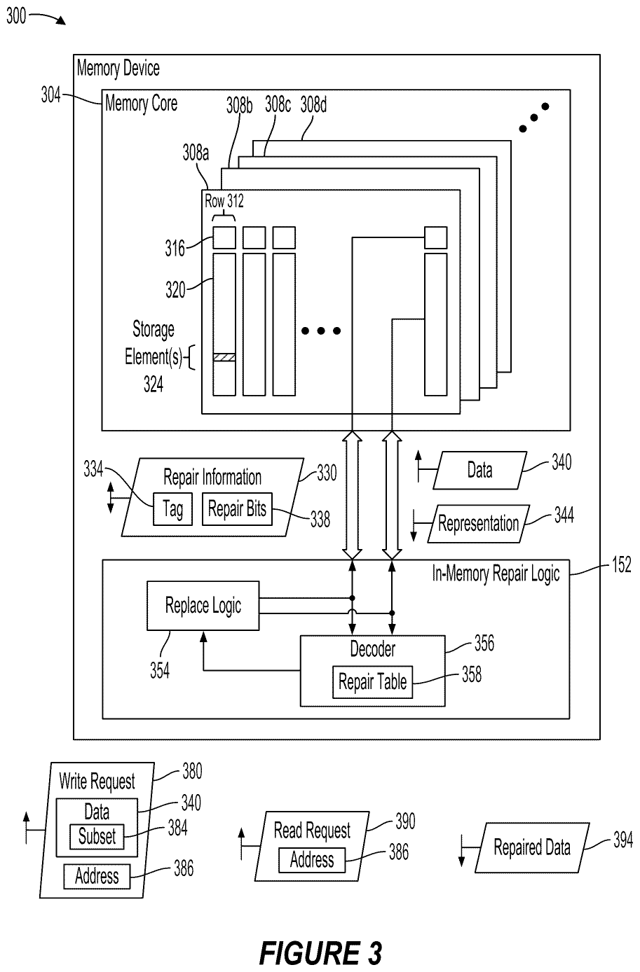

In some aspects, a memory device may include in-memory repair logic to initiate, perform, or control one or more operations described herein. For example, referring again to FIG. 1, the memories 150-1, 150-2, 150-3, and 150-4 may include in-memory repair logic 152-1, 152-2, 152-3, and 152-4, respectively. As another example, referring again to FIG. 2, the memory array 175 may include in-memory repair logic 152. In some examples, the in-memory repair logic 152 may be associated with an in-memory repair scheme that is distinct from an error correction code (ECC) scheme 292 of the memory system 250 and that is distinct from a row or column replacement scheme 294 of the memory system 250. Some illustrative examples that may be associated with in-memory repair logic 152 are described further with reference to FIG. 3.

FIG. 3 illustrates an example of a memory device 300 that supports in-memory repair information for data subsets. In some examples, the memory device 300 may correspond to one or more features of FIG. 1 or FIG. 2. For example, the memory device 300 may correspond to one or more the memories 150-1 to 150-4 of FIG. 1 or the memory array 175 of FIG. 2. In some examples, the memory device 300 may include or may correspond to a memory die.

The memory device 300 may include a memory array (e.g., a memory core 304) and may further include control circuitry coupled to the memory core 304, such as in-memory repair logic 152. The memory core 304 may be coupled to the in-memory repair logic 152 via one or more buses or other connections. In some examples, the in-memory repair logic 152 may be coupled to the memory controller 130 of FIG. 1 or the memory controller 180 of FIG. 2.

The memory core 304 may include one or more memory banks, such as memory banks 308a, 308b, 308c, and 308d. In some examples, the memory banks 308a-d may correspond to or may include memory banks 0-m illustrated in FIG. 2. Each memory bank of the memory banks 308a-d may include multiple rows of storage elements (also referred to herein as pages of storage elements or physical pages of storage elements). For example, the memory bank 308a may include a representative row 312. In the example of FIG. 3, the row 312 may include storage elements 316 and storage elements 320.

The in-memory repair logic 152 may include replace logic 354 and a decoder 356. The decoder 356 may be coupled to the replace logic 354. The replace logic 354 and the decoder 356 may be coupled to the memory core 304.

During operation, the memory device 300 may receive requests to write data to and read data from the memory core 304. In some examples, the memory device 300 may receive the requests from the memory controller 130 of FIG. 1 or the memory controller 180 of FIG. 2. As an illustrative example, the memory device 300 may receive a write request 380 to write data 340 to the memory core 304. The write request 380 may specify an address 386 of the memory device 300. The address 386 may correspond to a row of storage elements of the memory device 300, such as the row 312. In some examples, the data 340 may correspond to a logical page of data, and the row 312 may correspond to a physical page that is to store the data 340.

The in-memory repair logic 152 may receive the address 386 and may determine whether the address 386 is associated with one or more defective storage elements. To illustrate, in the example of FIG. 3, the address 386 may correspond to the row 312, and the row 312 may include one or more storage elements 324 associated with a defect. In some examples, the in-memory repair logic 152 may store, or may access, a repair table 358. The repair table 358 may indicate whether a row of the memory core 304 includes one or more defective storage elements and may further indicate the location of any such storage element within the row. For example, the repair table 358 may indicate that the row 312 includes the one or more storage elements 324 associated with a defect. Further, the repair table 358 may indicate a location of the one or more storage elements 324, such as a position of the one or more storage elements 324 within the row 312.

In some examples, at least some information of the repair table 358 may be generated and stored to the memory device 300 during fabrication or manufacturing of the memory device 300, such as during one or more of a functional test, a parametric test, a structural test, a reliability test, or a package test that may be associated with the memory device 300. Alternatively, or in addition, the memory device 300 may determine at least some information of the repair table 358 during a user operation mode, such as during a self-test of the memory device 300. One example of such a self-test is a memory built-in self-test (MBIST). Other examples are also within the scope of the disclosure.

As referred to herein, a “defect” may refer to reduced reliability of one storage element as compared to another storage element. For example, if a storage element is unable to store a value for at least a threshold time interval, and if other storage elements are able to store the value for at least the threshold time interval, the storage element may be referred to as having a defect. In some examples, defects may occur during device manufacturing, during production (e.g., packaging), during end user operation (e.g., as a result of physical wear due to read and write operations), in one or more other contexts, or a combination thereof.

In some examples, the in-memory repair logic 152 may determine, based on the repair table 358, that the address 386 is not associated with a defective storage element of the memory core 304. In such examples, the memory device 300 may store the data 340 to the memory core 304 without generating repair information associated with the data 340.

In some other examples, the in-memory repair logic 152 may determine, based on the repair table 358, that the address 386 is associated with one or more defective storage elements of the memory core 304. To illustrate, in the example of FIG. 3, the address 386 may correspond to the row 312, and the row 312 may include the one or more storage elements 324 associated with a defect. In such examples, the in-memory repair logic 152 may generate repair information 330 associated with the data 340. For example, the in-memory repair logic 152 may copy a subset 384 of the data 340 to generate repair bits 338. The repair bits 338 may correspond to a copy of the subset 384 that is to replace the subset 384 in connection with one or more read processes. The repair bits 338 may include data that is to be written to the one or more storage elements 324. The repair bits 338 may further include other data that is to be written to other (non-defective) storage elements of the row 312, such as neighbor storage elements of the one or more storage elements 324.

In some examples, the repair information 330 may also include a tag 334. The tag 334 may include metadata or other information associated with the repair bits 338. In some examples, the tag 334 may identify one or more of a location of the row 312 within the memory core 304 or a location of the repair bits 338 within the row 312. Some illustrative examples that may be associated with the tag 334 are described further below.

The memory device 300 may store the data 340 to the row 312. In some implementations, the memory device 300 may also store the repair information 330 to the row 312. For example, the memory device 300 may store the repair information 330 to the storage elements 316 and may store the data 340 to the storage elements 316. In such examples, the storage elements 316 may correspond to a portion of the row that is reserved for the repair information 330. Other examples are also within the scope of the disclosure. For example, in other implementations, the repair information 330 may be stored to another row of the memory bank 308a or to another location of the memory core 304.

In some examples, after storing the repair information 330 and the data 340 to the memory core 304, the memory device 300 may receive a read request 390 for the data 340. For example, the memory device 300 may receive the read request 390 from a memory controller, such as the memory controller 130 of FIG. 1 or the memory controller 180 of FIG. 2. The read request 390 may specify an address of the memory device 300, such as the address 386 of the row 312.

Based on receiving the read request 390, the memory device 300 may initiate a read of the repair information 330 and the data 340, such as by reading contents of the row 312. Reading the contents of the row 312 may result in a representation 344 of the data 340 that may differ from the data 340 due to a defect associated with the one or more storage elements 324. For example, one or more values stored by the one or more storage elements 324 may be unreliable as a result of the defect. As a result, the representation 344 may differ from the data 340.

The in-memory repair logic 152 may receive the repair information 330 and the representation 344 of the data 340 from the memory core 304. The in-memory repair logic 152 may replace some of the representation 344 of the data 340 with the repair bits 338 (e.g., by “swapping” out a representation of the subset 384 with the repair bits 338) to generate repaired data 394. In some examples, the in-memory repair logic 152 may repair the representation 344 with the repair bits 338 based on the tag 334.

The in-memory repair logic 152 may output the repaired data 394 in connection with the read request 390. For example, based on the repair information 330 and the representation 344 of the data 340, the memory device 300 may provide the repaired data 394 to a memory controller in accordance with the read request 390 (e.g., after repairing the representation 344 using the repair bits 338 such that the repaired data 394 corresponds to the data 340). In some examples, the memory controller may correspond to the memory controller 130 of FIG. 1 or the memory controller 180 of FIG. 2.

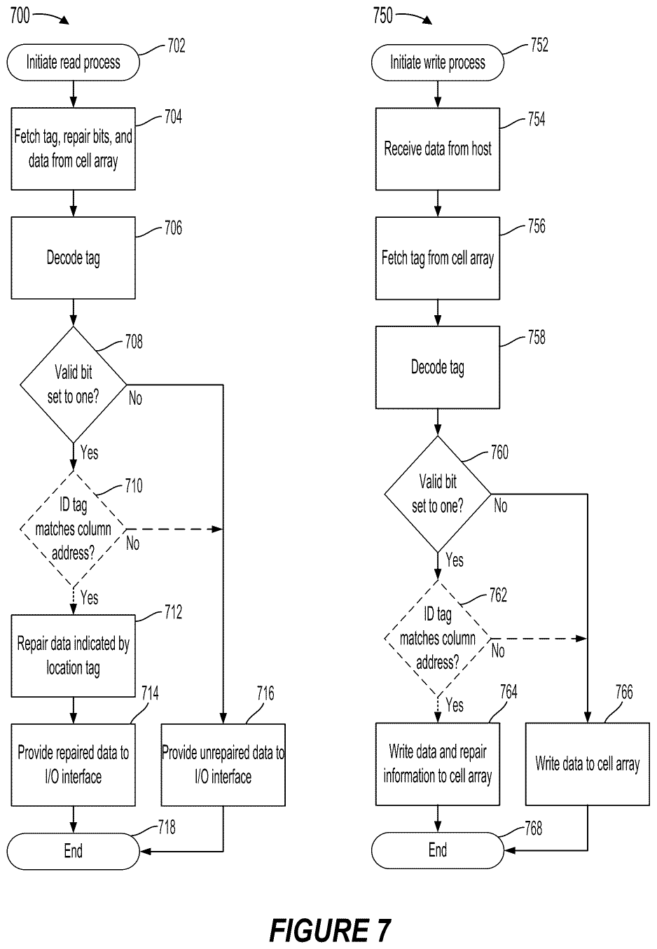

In some implementations, the repair information 330 and the data 340 may be written to and read from the row 312 as a single transaction (e.g., atomically). Further, in some implementations, the memory device 300 may perform write operations as read-modify-write operations. For example, in response to receiving the write request 380, the memory device 300 may read contents of the row 312 and may modify the contents of the row 312 by writing the repair information 330 and the data 340 to the row 312. Some further examples are described with reference to FIG. 7.

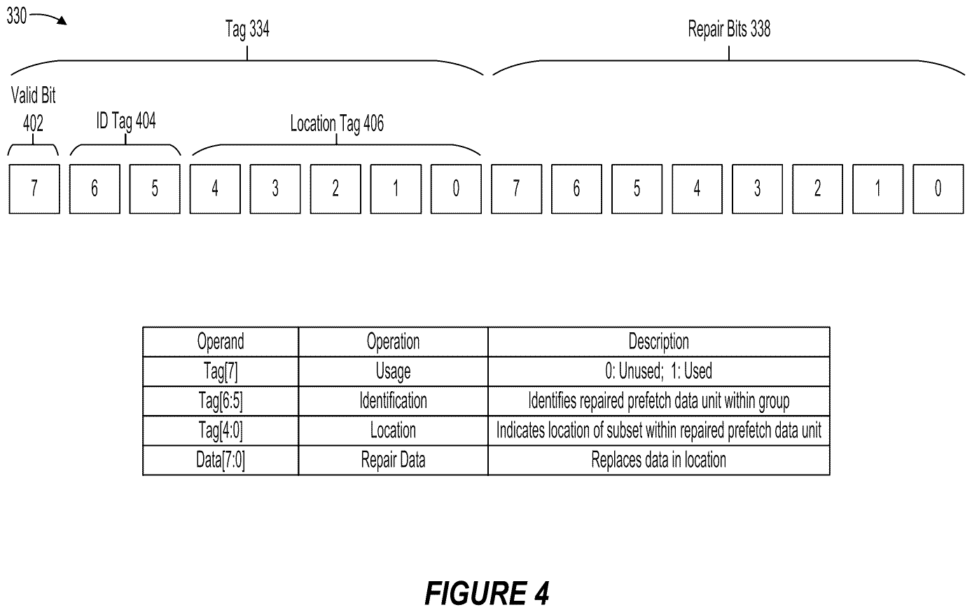

FIG. 4 illustrates examples of features that may be associated with the repair information 330 for in-memory repair information for data subsets. In the example of FIG. 4, the repair information 330 may include the tag 334 and the repair bits 338.

The tag 334 may include a valid bit 402. The valid bit 402 may have a value indicating whether the repair information 330 is to be used during a read operation associated with the row 312. For example, the in-memory repair logic 152 may set the valid bit 402 to a value of one to indicate that the repair information 330 is to be used during a read operation associated with the row 312. In this case, the valid bit 402 may indicate that the repair bits 338 are to replace the subset 384 of the data 340. In other cases, the valid bit 402 may have a value of zero to indicate that the repair information 330 is not to be used during a read operation associated with the row 312. To illustrate, in some such examples, the repair information 330 may be set to a default value, such as all zero values. In this case, the valid bit 402 may have a zero value indicating that the repair information 330 is not valid. In the example of FIG. 4, the valid bit 402 may include bit 7 of the tag 334, where, a logic zero value of bit 7 of the tag 334 may indicate that the repair information 330 is unused (e.g., is invalid), and where a logic one value of bit 7 of the tag 334 may indicate that the repair information 330 is used (e.g., is valid).

In some examples, the decoder 356 may be configured to identify the value of the valid bit 402 and to provide an enable signal to the replace logic 354 based on the value of the valid bit 402. In some examples, the decoder 356 may set a first value of the enable signal if the valid bit 402 has a logic one value and may set a second value of the enable signal if the valid bit 402 has a logic zero value. The first value may enable the replace logic 354 to repair data (e.g., by replacing data of the representation 344 with the repair bits 338), and the second value may disable the replace logic 354 from such repair operations.

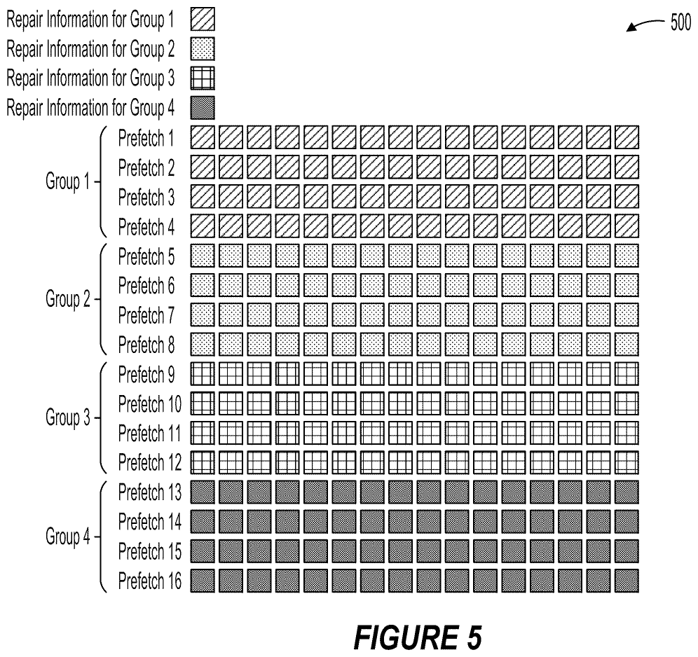

The tag 334 may further include an identification tag 404. In some examples, the identification tag 404 may include bits 5 and 6 of the tag 334. In some examples, the identification tag 404 may indicate a particular prefetch data unit of a group of prefetch data units, where the particular prefetch data unit is associated with the repair information 330. To illustrate, in one example, the group of prefetch data units may include four prefetch data units each associated with a respective set of values of bits 5 and 6 (e.g., “00,” “01,” “10,” and “11”). Some such examples are described further with reference to the example of FIG. 5.

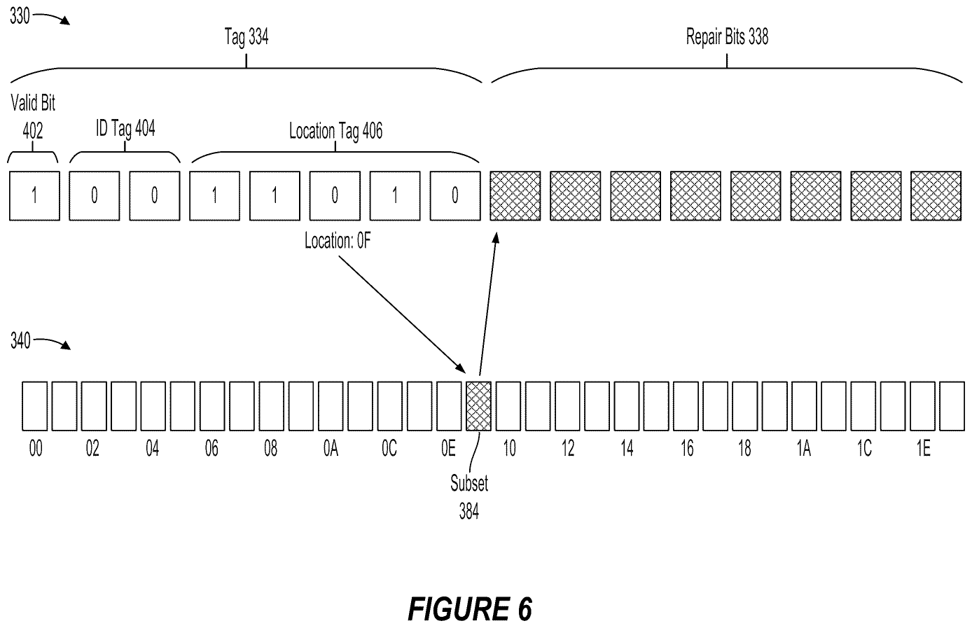

The tag 334 may further include a location tag 406. In some implementations, the location tag 406 may include bits 0, 1, 2, 3, and 4 of the tag 334. In some examples, the data 340 may include multiple different subsets including the subset 384, and the location tag 406 may indicate that, among the multiple different subsets, the subset 384 is associated with the repair bits 338. To illustrate, in one example, the data 340 may be associated with sixteen different subsets (including the subset 384), where each subset may be associated with a respective set of values of bits 0-4. In some examples, the data 340 may correspond to a particular prefetch data unit of a group of prefetch data units, and the identification tag 404 may indicate that, among the group of prefetch data units, the particular prefetch data unit is associated with the repair bits 338. Some such examples are described further with reference to the example of FIG. 6.

In the illustrative example of FIG. 4, the tag 334 and the repair bits 338 may each include eight bits. In such examples, the repair information 330 may correspond to a set of sixteen bits. Other examples are also within the scope of the disclosure. For example, some implementations, the tag 334 may include more than or fewer than eight bits. Alternatively, or in addition, the repair bits 338 may include more than or fewer than eight bits. Further, in FIG. 4, a ratio of bits of the tag 334 to the repair bits 338 may correspond to one (e.g., where the tag 334 to the repair bits 338 may each include eight bits). In some other examples, the ratio may be greater than one (e.g., where the identification tag 404 may be omitted from tag 334, which may result in a ratio of 6/8) or less than one (e.g., where the data 340 is divided into more 32 subsets, reducing a quantity of the repair bits 338).

Further, it should be appreciated that the tag 334 may include other information not depicted in the example of FIG. 4 (alternatively or in addition to one or more of the valid bit 402, the identification tag 404, or the location tag 406. To illustrate, the tag 334 may include another bit indicating whether the data 340 is correctable or uncorrectable. Alternatively, or in addition, the tag 334 may include an additional bit indicating whether the data 340 is valid or invalid. Other examples are also within the scope of the disclosure.

FIG. 5 illustrates an example of a repair scheme 500 that supports in-memory repair information for data subsets. In connection with the example of FIG. 5, the memory device 300 of FIG. 3 may store multiple groups of prefetch data units (also referred to as prefetches). For example, a first group (group 1) may include prefetches 1-4, and a second group (group 2) may include prefetches 5-8. As additional examples, a third group (group 3) may include prefetches 9-12, and a fourth group (group 4) may include prefetches 13-16. Although the example of FIG. 5 may illustrate four groups of fourth prefetches each, other examples are also within the scope of the disclosure. In some examples, a prefetch data unit may include 64 bits, 128 bits, 256 bits, or another quantity of bits.

In the example of FIG. 5, each group of the multiple groups of prefetch data units may be associated with respective repair information. In some examples, the repair information for one such group of prefetch data units may correspond to the repair information 330 of FIG. 3. Further, the data 340 of FIG. 3 may correspond to one of the prefetches 1-16. As an illustrative example, the repair information 330 may correspond to the repair information for group 1, and the data 340 may correspond to prefetch 1.

To further illustrate, the data 340 of FIG. 3 may correspond to a particular prefetch data unit (e.g., any of the prefetch data units 1-16 of FIG. 5) of a group of prefetch data units (e.g., any of the groups 1-4 of FIG. 5). The repair information 330 of FIG. 3 may be reserved for the group of prefetch data units. For example, the repair information 330 may correspond to the repair information for group 1, group 2, group 3, or group 4. The identification tag 404 may indicate that, among the group of prefetch data units, the particular prefetch data unit is associated with the repair information 330.

In some examples, based on reading any prefetch data unit of a group, the memory device 300 may automatically also read the corresponding repair information for the group (irrespective of whether the repair information is associated with the prefetch data unit). Such an implementation may reduce latency as compared sequentially reading the prefetch data unit, determining whether the prefetch data unit is associated with repair information, and then reading the repair information if the prefetch data unit is associated with the repair information.

To illustrate, if the memory device 300 receives a read request for prefetch 1, the memory device 300 may read both prefetch 1 and the repair information for group 1. In one example, the identification tag 404 may indicate that the repair information for group 1 is associated with prefetch 1. In one example, prefetch 1 may be associated with a set of values of “00,” and the identification 334 may be set to “00” to indicate that the repair information for group 1 is associated with prefetch 1. In this case, the memory device 300 may repair prefetch 1 based on the repair information for group 1 (e.g., by replacing data of the representation 344 with the repair bits 338).

Further, if the memory device 300 receives a read request for at least one other prefetch data unit of group 1 (such as prefetch 2, 3, or 4), the memory device 300 may read the repair information for group 1 irrespective of whether the repair information is related to the at least one other prefetch data unit. The memory device 300 may determine, based on the identification tag 404, that the repair information for group 1 is not related to the at least one other prefetch data unit (e.g., where the identification tag 404 does not include a set of values associated with the at least one other prefetch data unit).

FIG. 6 illustrates examples of features that may be associated with the repair information 330 and the data 340 for in-memory repair information for data subsets. In the example of FIG. 6, the data 340 may include multiple different subsets including the subset 384. The location tag 406 may indicate that, among the multiple different subsets, the subset 384 is associated with the repair information 330. For example the subset 384 may be associated with a hexadecimal index of “0F,” which may be represented in the location tag 406 as a set of values of “01011.”

Further, the subset 384 may be included in the repair information 330 as the repair bits 338. In some examples, the data 340 may correspond to a prefetch data unit having an index value of “00,” as indicated in the identification tag 404. The valid bit 402 may be set to a value of “1” to indicate that the repair information 330 is valid for the data 340.

In some examples, each subset of the data 340 illustrated in the example of FIG. 6 may include a first quantity of bits of the data 340, and one or more storage elements 324 of FIG. 3 may include a second quantity of storage elements, where the first quantity is greater than or equal to the second quantity. To further illustrate, in some circumstances, the first quantity may be greater than the second quantity. As an example, if the one or more storage elements 324 include only one storage element, and if each subset of the data 340 includes eight bits, then the repair bits 338 may include one bit associated with a defective storage element and may further include seven bits associated with non-defective storage elements. Other examples are also within the scope of the disclosure.

FIG. 7 illustrates examples of a read process 700 and a write process 750 that support in-memory repair information for data subsets. In some examples, the read process 700 and the write process 750 may be performed by a memory device, such as any of the memories 150-1 to 150-4 of FIG. 1, the memory array 175 of FIG. 2, the memory device 300 of FIG. 3, or another memory device.

The read process 700 may initiate, at 702. For example, the memory device 300 may receive the read request 390.

The read process 700 may further include fetching a tag, repair bits, and data from a cell array, at 704. For example, the read request 390 may specify the address 386, and the memory device 300 may fetch the representation 344 of the data 340 from the row 312. The memory device 300 may also fetch the tag 334 and the repair bits 338 (e.g., from the row 312 or from another storage location).

The read process 700 may further include decoding the tag, at 706. For example, the in-memory repair logic 152 may input the tag 334 (or a portion of the tag 334) to the decoder 356 to enable the decoder 356 to decode the tag 334.

The read process 700 may further include determining whether a valid bit of the tag is set to one, at 708. For example, decoding the tag 334 may include determining whether the valid bit 402 indicates that the repair information 330 is valid.

If the valid bit of the tag is set to one, the read process 700 may optionally include determining whether an identification tag matches a column address, at 710. The identification tag may correspond to the identification tag 404. To illustrate, the repair information may be shared among a group of prefetch data units, and the identification tag may indicate which prefetch data unit of the group is associated with the repair information.

If the identification tag matches the column address, the read process 700 may further include repairing data indicated by a location tag, at 712. For example, the in-memory repair logic 152 may input the repair information 330 (or a portion thereof) and the representation 344 of the data 340 to the replace logic 354. The replace logic 354 may replace data of the representation 344 with the repair bits 338 (e.g., to correct one or more data errors that may be attributable to physical wear associated with the one or more storage elements 324). The replace logic 354 may output repaired data, such as the repaired data 394.

The read process 700 may further include providing repaired data to an input/output (I/O) interface, at 714. For example, the replace logic 354 may output repaired data, such as the repaired data 394, to an I/O interface that may be included in the memory device 300. The I/O interface may be accessible to another device, such as one or more of the host 110, the memory controller 130, or the memory controller 180. The read process 700 may terminate, at 718.

Alternatively, if the valid bit is set to zero, or if the identification tag fails to match the column address, the read process 700 may further include providing unrepaired data to the I/O interface, at 716. For example, the memory device 300 may decline to input the repair information 330 (or a portion thereof) and the representation 344 of the data 340 to the replace logic 354 (e.g., by bypassing the replace logic 354). The read process 700 may terminate, at 718.

The write process 750 may initiate, at 752. For example, the memory device 300 may receive a write request, such as the write request 380 or another write request (e.g., subsequent to writing the data 340 in connection with the write request 380).

The write process 750 may also include receiving data from a host or another device, at 754. For example, the memory device 300 may receive the data 340 or other data from one or more of the host 110, the memory controller 130, or the memory controller 180.

The write process 750 may further include fetching a tag from a cell array, at 756. In some examples, the write request may specify an address 386 associated with a group of prefetch data units, and the repair information 330 may be associated with the group of prefetch data units. In this example, the memory device 300 may fetch the tag 334 the repair information 330.

The write process 750 may further include decoding the tag, at 758. For example, the in-memory repair logic 152 may input the tag 334 (or a portion of the tag 334) to the decoder 356 to enable the decoder 356 to decode the tag 334.

The write process 750 may further include determining whether a valid bit of the tag is set to one, at 760. For example, decoding the tag 334 may include determining whether the valid bit 402 indicates that the repair information 330 is valid.

If the valid bit of the tag is set to one, the write process 750 may optionally include determining whether an identification tag matches a column address, at 762. The identification tag may correspond to the identification tag 404. If the identification tag matches the column address, the write process 750 may further include writing data and repair information to a cell array, at 764. For example, the memory device 300 may write the repair information 330 and the data 340 to the memory core 304. The write process 750 may terminate, at 768.

Alternatively, if the valid bit is set to zero, or if the identification tag fails to match the column address, the write process 750 may further include writing data to the cell array, at 766. For example, the memory device 300 may write the data 340 to the memory core 304 (e.g., without writing corresponding repair information to the memory core 304). The write process 750 may terminate, at 768.

The write process 750 may include or may be referred to as a read-modify-write process. For example, upon receiving the data (at 754), the tag may be fetched (at 756) and decoded (758). After determining whether the valid bit is set to one (at 760), the data may then be written to the cell array (at 764 or at 766) based on the value of the valid bit (thus modifying the contents of the cell array).

Accordingly, FIG. 7 illustrates example operations that may be performed in at least some implementations in which repair information is shared among a group of prefetch data units. In such examples, ID tags (such as the identification tag 404) may be used to indicate that repair information (such as the repair information 330) is associated with a particular prefetch data unit among the group of prefetch data units. Other examples are also within the scope of the disclosure. To illustrate, in some other implementations, each such prefetch data unit may be associated with corresponding repair information. In such examples, determining whether an identification tag matches a column address, at 710, and at 760, may be omitted from the read process 700 and the write process 750, respectively, and the identification tag 404 may be omitted from the repair information 330.

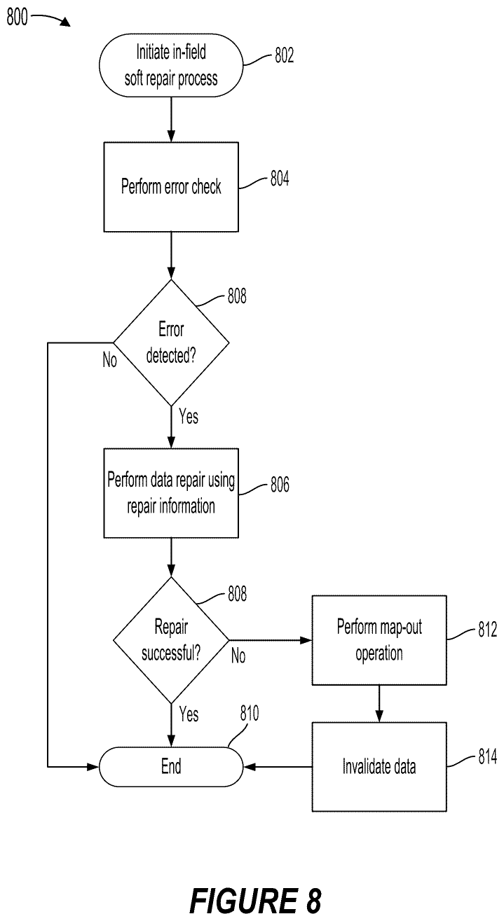

FIG. 8 illustrates an example of an in-field soft repair process 800 for in-memory repair information for data subsets. In some examples, the in-field soft repair process 800 may be performed by a memory device, such as any of the memories 150-1 to 150-4 of FIG. 1, the memory array 175 of FIG. 2, the memory device 300 of FIG. 3, or another memory device.

The in-field soft repair process 800 may initiate, at 802. In some examples, the in-field soft repair process 800 be performed (and may initiate) in connection with a read process to read data, such as the read process 750 (e.g., to read the data 340) or another read process. In some examples, the in-field soft repair process 800 may be initiated based on receiving the read request 390 of FIG. 3 and may include reading the representation 344 of the data 340 (e.g., from the row 312).

The in-field soft repair process 800 may further include performing an error check associated with the data, at 804. For example, the error check may include identifying whether the representation 344 of the data 340 includes one or more errors. In some examples, the error check may be performed using an error correction code (ECC), such as, for example, a single-error correction, double-error detection (SECDED) code, a Reed-Solomon code, Bose-Chaudhuri-Hocquenghem (BCH) code, a low-density parity check (LDPC) code, or another code. To illustrate, in some implementations, the error check may be performed by an in-memory ECC engine that may be included in the memory device 300. In some other examples, the error check may be performed by another ECC engine, such as an ECC engine that may be included in the host 110, the memory controller 130, or the memory controller 180. In some examples, the error check may be performed in accordance with the ECC scheme 292 of FIG. 2.

The in-field soft repair process 800 may further include determining whether an error is detected in connection with the error check, at 808. If no error is detected, the in-field soft repair process 800 may terminate, at 810.

In some other examples, if one or more errors are detected, the in-field soft repair process 800 may include performing data repair using repair information, at 806. For example, the memory device 300 may input the repair bits 338 and the representation 344 to the replace logic 354 to repair the representation 344 based on the repair bits 338 (e.g., by “swapping out” data of the representation 344 with the repair bits 338 in order to correct the one or more errors and to generate the repaired data 394). Further, the locations of one or more such errors may be logged (e.g., in the repair table 358).

The in-field soft repair process 800 may further include determining whether the repair is successful, at 808. In some examples, the error check may be reperformed to determine whether the repair is successful. In one example, reperforming the error check may indicate that no error is present in the repaired data 394, and the repair may be determined to be successful. In some other cases, reperforming the error check may indicate that one or more errors are present in the repaired data 394, and the repair may be determined to be unsuccessful.

If the repair is successful, the in-field soft repair process 800 may terminate, at 810. In some other cases, the repair may be unsuccessful, and the in-field soft repair process 800 may include one or more other operations, such as a next level data integrity control operation. In some examples, the one or more operations may include performing a map-out operation, at 812, and may further include invalidating the data, at 814. Other examples are also within the scope of the disclosure. For example, in other implementations, the one or more operations may include a poisoning operation, a row-repair operation, or another operation.

To further illustrate some examples, in connection with FIG. 8, an error may be detected using an in-memory, on-die ECC engine or using an ECC engine of a host system. If an error is detected using the on-die ECC engine, and if the error is correctable (and the location of the error can be identified), the on-die ECC engine may correct the error and may attempt to repair the defective cell by updating the tag of the associated repair resource. If the tag of the associated repair resource indicates the repair resource is in use, the data may be be sent to the host system and information may be logged to indicate the data is unrepaired but recovered (or corrected) by the on-die ECC engine. If an error is detected by the ECC engine of the host system, and if the error is correctable (and location of the error can be identified), the ECC engine of the host system may attempt to repair the defective cell by updating the tag of the associated repair resource. The tag update per each data unit (e.g., per each prefetch data unit) may be achieved using a dedicated command. The command may be asserted with the same address as the location of the error. The tag update result may be indicated to the host system at one or more I/O lanes. If the repair is unavailable (e.g., if the associated repair resource is used), the host system may attempt to use the next level data integrity control such as poisoning, mapping-out, or repairing the row, etc.

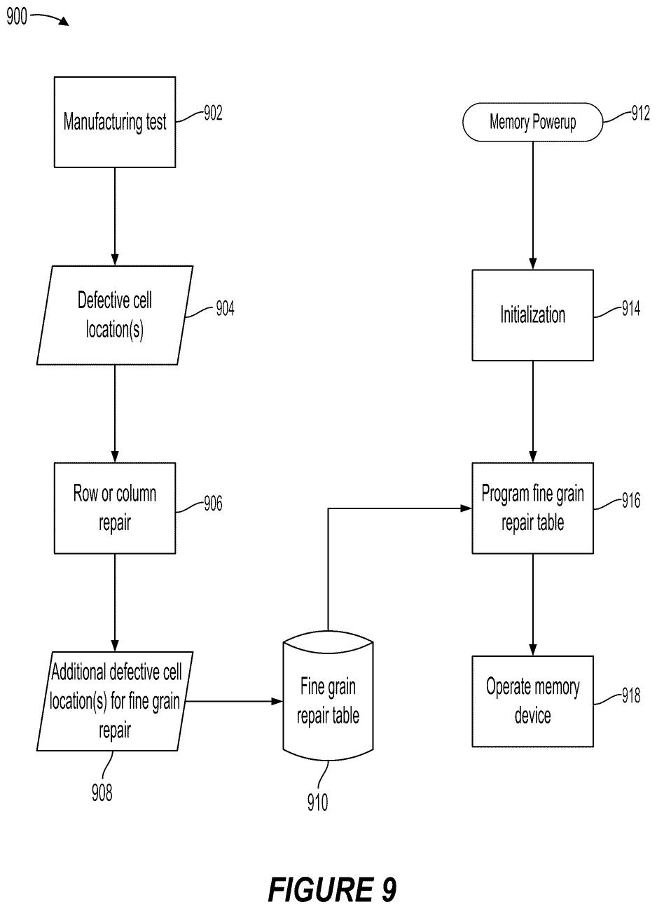

FIG. 9 illustrates example operations 900 that support in-memory repair information for data subsets. In some examples, the operations 900 may be performed in connection with a memory device, such as any of the memories 150-1 to 150-4 of FIG. 1, the memory array 175 of FIG. 2, the memory device 300 of FIG. 3, or another memory device.

The operations 900 may include performing a manufacturing test of the memory device, at 902. For example, the manufacturing test may include or may correspond to one or more of a functional test, a parametric test, a structural test, a reliability test, or a package test that may be associated with the memory device 300. Performing the manufacturing test may include identifying one or more defective cell locations 904. The operations 900 may further include performing a row repair or column repair, at 906. For example, a row containing one or more defective storage elements may be “swapped out” for a spare row of the memory device 300 (e.g., using one or more fuses that may be included in the memory device 300). Alternatively, or in addition, a column containing one or more defective storage elements may be “swapped out” for a spare column of the memory device 300 (e.g., using one or more fuses that may be included in the memory device 300). In some examples, the row and column repair may be performed in accordance with the row or column replacement scheme 294 of FIG. 2.

The operations 900 may further include identifying one or more additional defective cell locations 908 for fine grain repair. To illustrate, in some circumstances, a quantity of defect cells of the memory device 300 may exceed a quantity of fuses of the memory device 300 that are available for repair. In such examples, locations of the “leftover” defective cells that are not repairable using fuses may be identified as the one or more additional defective cell locations 908. In some examples, the one or more additional defective cell locations 908 may include cell locations of the one or more storage elements 324 of FIG. 3.

The operations 900 may further include generating a fine grain repair table 910. The fine grain repair table 910 may indicate the one or more additional defective cell locations 908. In some examples, the fine grain repair table 910 may include or may correspond to the repair table 358 of FIG. 3.

The operations 900 may further include initiating a memory powerup of the memory device, at 912. In some examples, the memory powerup may be performed in connection with the manufacturing test or during another mode of operation, such as during a product assembly operation (e.g., where the host 110 is connected to the memory device 300) or an end user mode (also referred to as a mission mode).

The operations 900 may include initialization, at 914. For example, after connecting the host 110 to the memory device 300, communications between the host 110 and the memory device 300 may be initialized via a handshake procedure. In connection with the initialization, the fine grain repair table 910 may be programmed (or updated), at 916. For example, programming the fine grain repair table 910 may include providing the fine grain repair table 910 from the host 110 (or from another device) to the memory device 300. Further, in some cases, the fine grain repair table 910 may be loaded or updated via a subsequent programming (e.g., by loading the fine grain repair table 910 from a non-volatile memory during a mission mode of operation upon powerup).

To further illustrate, programming the fine grain repair table 910 may include storing the fine grain repair table 910 to a non-volatile memory or read-only memory (ROM) of the memory device 300, loading the fine grain repair table 910 to a volatile memory or cache of the memory device 300 (e.g., after retrieving the fine grain repair table 910 from the non-volatile memory or ROM), one or more other operations, or a combination thereof. In some examples, the fine grain repair table 910 may be provided to the memory device 300 through a separate non-volatile memory in addition to the memory device 300 or may be stored via a secured network and provided via the secured network on a per-request basis. In one example, the fine grain repair table 910 may be provided to the memory device 300 via a serial presence detect (SPD) technique. In some cases, the fine grain repair table 910 may be one or more of encoded, hashed, encrypted, scrambled, or compressed (e.g., to protect manufacturing information while reducing a data size of the fine grain repair table 910). In some cases, the memory device 300 may include an encryption key (e.g., a private encryption key) to decrypt the fine grain repair table 910. Further, programming of the fine grain repair table 910 (e.g., during powerup) may be achieved using a dedicated command and a dedicated data transaction timing associated with the programming.

The operations 900 may further include operating the memory device, at 918. For example, operating the memory device may include one or more of receiving the write request 380, receiving the read request 390, writing the data 340 to the memory device 300, repairing the representation 344 of the data 340 using the repair information 330, or one or more other operations.

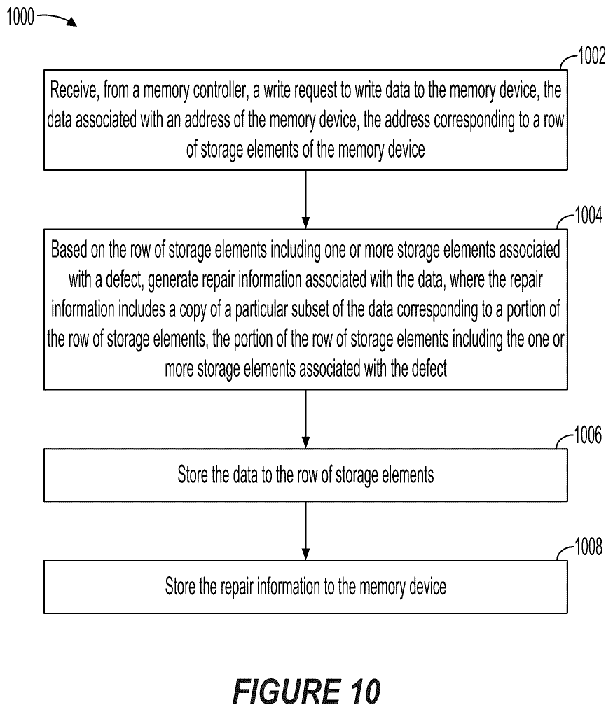

FIG. 10 illustrates an example of a process 1000 that supports in-memory repair information for data subsets. In some examples, the process 1000 may be performed by a memory device, such as one of the memories 150-1 to 150-4 of FIG. 1, the memory system 250 of FIG. 2, the memory array 175 of FIG. 2, the memory device 300 of FIG. 3, or another memory device.

The process 1000 includes receiving, from a memory controller, a write request to write data to the memory device, at 1002. The data is associated with an address of the memory device, and the address corresponds to a row of storage elements of the memory device. For example, the memory device 300 may receive the write request 380 to write the data 340 to the memory device 300. The data 340 may be associated with an address 386 of the memory device 300, and the address 386 may correspond to the row 312 of the memory device 300.

The process 1000 further includes, based on the row of storage elements including one or more storage elements associated with a defect, generating repair information associated with the data, at 1004. The repair information includes a copy of a particular subset of the data corresponding to a portion of the row of storage elements, and the portion of the row of storage elements includes the one or more storage elements associated with the defect. For example, based on the row 312 including the one or more storage elements 324 associated with a defect, the memory device 300 may generate the repair information 330 associated with the data 340. The repair bits 338 may include or may correspond to a copy of the subset 384 of the data 340 and may correspond to a portion of the row 312. The portion of the row 312 may include the one or more storage elements 324. Further, in some cases, the portion of the row 312 may additionally include one or more non-defective storage elements. As an illustrative example, if the one or more storage elements 324 include only one storage element, and if the subset 384 includes eight bits, then the repair bits 338 may include one bit associated with a defective storage element and may further include seven bits associated with non-defective storage elements. Other examples are also within the scope of the disclosure.

The process 1000 further includes storing the data to the row of storage elements, at 1006. For example, the memory device 300 may store the data 340 to the row 312.

The process 1000 further includes storing the repair information to the memory device, at 1008. For example, the memory device 300 may store the repair information 330 to the row 312.

In some aspects, a memory device (e.g., one of the memories 150-1 to 150-4 of FIG. 1, the memory system 250 of FIG. 2, the memory array 175 of FIG. 2, the memory device 300 of FIG. 3, or another memory device) may include a memory array and control circuitry coupled to the memory array. The control circuitry may be configured to initiate, perform, or control, one or more operations described with reference to the memory device 300. In some examples, the memory array may include the memory core 304, and the control circuitry may include the in-memory repair logic 152. Further, in some examples, the control circuitry may include one or more processors configured to initiate, control, or perform the operations. In addition, in some implementations, the memory device 300 may include a processing system including one or more memories and one or more processors coupled to the one or more memories. The one or more processors may include or may correspond to the in-memory repair logic 152, and the one or more memories may include or may correspond to the memory core 304.

One or more features described herein may improve performance or reduce cost associated with a memory device. To illustrate, a conventional row or column replace scheme may need to devote an entire spare row or column to correct a relatively small quantity of defective storage elements (e.g., a single defective storage element of a row), which may be inefficient. By using repair information (such as the repair information 330) as described herein, a more “fine grain” approach may be used to correct a relatively small quantity of defective storage elements and may more closely match a quantity of replacement storage elements to defective storage elements. In addition, in some scenarios, the repair information may be used as an auxiliary (or “fine grain”) repair scheme in addition to a primary repair scheme of the memory device 300, such as one or more of the ECC scheme 292 or the row or column replacement scheme 294. In this example, the repair information 330 may be selectively generated based on a quantity of errors associated with the row 312 exceeding an error correction capability of the ECC scheme 292, based on a quantity of defective rows (or columns) of the memory device 300 exceeding a quantity of spare rows (or columns) of the memory device 300, or both. Further, use of the repair information may enable a reduced quantity of spare rows of columns, which may occupy die area and increase device cost. As a result, data loss associated with errors in data may be reduced or avoided while also decreasing cost and reducing die size overhead of a memory device.

Further, in some implementations, an in-memory repair scheme using repair information as described herein may improve performance as compared to some other techniques, such as in-memory ECC scheme that involves performing error correction on a memory die. In some devices, in-memory ECC schemes may correct errors in data that occur due to physical defects while “hiding” the existence of such physical defects from other devices or components, such as a host device. As a result, the host device may be unable to perform remedial operations associated with the physical defects, such as quarantining a memory area containing a physical defect. Further, some in-memory ECC schemes may involve a significant additional quantity of bits for error-correcting information (e.g., parity bits), which may be unused or wasted if a quantity of errors in data exceeds an error correcting capability of the particular ECC scheme (e.g., in the case of multiple errors with a single-error correction code). Additionally, in-memory ECC schemes may be less robust or effective than other ECC schemes (such as ECC schemes implemented at a memory controller or at a host) and may in some cases generate additional errors if physical defects cause the quantity of errors in data to exceed the error correcting capability of the particular ECC scheme. As a result, use of an in-memory repair scheme may reduce or avoid the need for in-memory ECC schemes to correct errors in data, improving performance and reducing cost and die size overhead of a memory device.

In a first aspect, a memory device includes a memory array and control circuitry coupled to the memory array. The control circuitry is configured to receive, from a memory controller, a write request to write data to the memory array. The data is associated with an address of the memory array, and the address corresponds to a row of storage elements of the memory array. The control circuitry is further configured to generate repair information associated with the data based on the row of storage elements including one or more storage elements associated with a defect. The repair information includes a copy of a particular subset of the data corresponding to a portion of the row of storage elements, and the portion of the row of storage elements includes the one or more storage elements associated with the defect. The control circuitry is further configured to store the data to the row of storage elements and to store the repair information to the memory array.

In a second aspect, in combination with the first aspect, the data includes multiple different subsets including the particular subset, and the repair information further includes a location tag indicating that, among the multiple different subsets, the particular subset is associated with the repair information.

In a third aspect, in combination with one or more of the first aspect or the second aspect, the repair information further includes a valid bit indicating that the copy is to replace the particular subset of the data.

In a fourth aspect, in combination with one or more of the first aspect through the third aspect, the control circuitry is further configured to receive a read request from a memory controller for the data and, based on the read request, to read the repair information and a representation of the data from the memory array. The control circuitry is further configured to replace the particular subset of the data with the copy based on the repair information to generate repaired data and to provide the repaired data to the memory controller in connection with the read request.

In a fifth aspect, in combination with one or more of the first aspect through the fourth aspect, the data corresponds to a particular prefetch data unit of a group of prefetch data units, and the repair information is reserved for the group of prefetch data units.

In a sixth aspect, in combination with one or more of the first aspect through the fifth aspect, the repair information further includes an identification tag indicating that, among the group of prefetch data units, the particular prefetch data unit is associated with the repair information.

In a seventh aspect, in combination with one or more of the first aspect through the sixth aspect, the control circuitry is further configured to receive a read request for at least one other prefetch data unit of the group of prefetch data units and to read the repair information with the at least one other prefetch data unit irrespective of whether the repair information is related to the at least one other prefetch data unit.

In an eighth aspect, in combination with one or more of the first aspect through the seventh aspect, the memory array is configured to store multiple groups of prefetch data units, and each group of the multiple groups of prefetch data units is associated with respective repair information.

In a ninth aspect, in combination with one or more of the first aspect through the eighth aspect, the control circuitry is further configured to receive a read request for the data from a memory controller, to receive the repair information and a representation of the data from the memory array, and based on the repair information and the representation of the data, to provide repaired data to the memory controller in accordance with the read request. The repaired data corresponds the data.

In a tenth aspect, in combination with one or more of the first aspect through the ninth aspect, the repair information is associated with an in-memory repair scheme that is distinct from an error correction code (ECC) scheme of the memory device and that is distinct from a row or column replacement scheme of the memory device.

In an eleventh aspect, a method of operation of a memory device includes receiving, from a memory controller, a write request to write data to the memory device. The data is associated with an address of the memory device, and the address corresponds to a row of storage elements of the memory device. The method further includes generating repair information associated with the data based on the row of storage elements including one or more storage elements associated with a defect. The repair information includes a copy of a particular subset of the data corresponding to a portion of the row of storage elements, and the portion of the row of storage elements includes the one or more storage elements associated with the defect. The method further includes storing the data to the row of storage elements and storing the repair information to the memory device.

In a twelfth aspect, in combination with the eleventh aspect, the data includes multiple different subsets including the particular subset, and the repair information further includes a location tag indicating that, among the multiple different subsets, the particular subset is associated with the repair information.

In a thirteenth aspect, in combination with one or more of the eleventh aspect through the twelfth aspect, the repair information further includes a valid bit indicating that the copy is to replace the particular subset of the data.

In a fourteenth aspect, in combination with one or more of the eleventh aspect through the thirteenth aspect, the method further includes receiving a read request from a memory controller for the data, reading the repair information and a representation of the data from the memory device based on the read request, replacing the particular subset of the data with the copy to generate repaired data based on the repair information, and providing the repaired data to the memory controller in connection with the read request.

In a fifteenth aspect, in combination with one or more of the eleventh aspect through the fourteenth aspect, the data corresponds to a particular prefetch data unit of a group of prefetch data units, and the repair information is reserved for the group of prefetch data units.

In a sixteenth aspect, in combination with one or more of the eleventh aspect through the fifteenth aspect, the repair information further includes an identification tag indicating that, among the group of prefetch data units, the particular prefetch data unit is associated with the repair information.

In a seventeenth aspect, in combination with one or more of the eleventh aspect through the sixteenth aspect, the method further includes receiving a read request for at least one other prefetch data unit of the group of prefetch data units and reading the repair information with the at least one other prefetch data unit irrespective of whether the repair information is related to the at least one other prefetch data unit.

In an eighteenth aspect, in combination with one or more of the eleventh aspect through the seventeenth aspect, the memory device stores multiple groups of prefetch data units, and each group of the multiple groups of prefetch data units is associated with respective repair information.

In a nineteenth aspect, a non-transitory computer-readable medium stores instructions executable by one or more processors of a memory device to initiate, perform, or control operations. The operations include receiving, from a memory controller, a write request to write data to the memory device. The data is associated with an address of the memory device, and the address corresponds to a row of storage elements of the memory device. The operations further include, based on the row of storage elements including one or more storage elements associated with a defect, generating repair information associated with the data. The repair information includes a copy of a particular subset of the data corresponding to a portion of the row of storage elements, and the portion of the row of storage elements includes the one or more storage elements associated with the defect. The operations further include storing the data to the row of storage elements and storing the repair information to the memory device.

In a twentieth aspect, in combination with the nineteenth aspect, the data includes multiple different subsets including the particular subset, and the repair information further includes a location tag indicating that, among the multiple different subsets, the particular subset is associated with the repair information.

In the figures, a single block may be described as performing a function or functions: The function or functions performed by that block may be performed in a single component or across multiple components, and/or may be performed using hardware, software, or a combination of hardware and software. To illustrate, various illustrative components, blocks, modules, circuits, and operations may be described in terms of functionality. Whether such functionality is implemented as hardware or software may depend upon the particular application and the overall system design. Skilled artisans may implement the described functionality in varying ways for each particular application, but such implementation decisions should not be interpreted as causing a departure from the scope of the disclosure. Also, the example devices may include components other than those shown, including components such as a processor, memory, and the like.

As used herein, the term “determine” or “determining” encompasses a wide variety of actions and, therefore, “determining” can include calculating, computing, processing, deriving, estimating, investigating, looking up (such as via looking up in a table, a database, or another data structure), inferring, ascertaining, or measuring, among other possibilities. Also, “determining” can include receiving (such as receiving information), accessing (such as accessing data stored in memory) or transmitting (such as transmitting information), among other possibilities. Additionally, “determining” can include resolving, selecting, obtaining, choosing, establishing and other such similar actions.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Certain components in a device or apparatus described as “means for accessing,” “means for receiving,” “means for sending,” “means for using,” “means for selecting,” “means for determining,” “means for normalizing,” “means for multiplying,” or other similarly-named terms referring to one or more operations on data, such as image data, may refer to processing circuitry (such as application specific integrated circuits (ASICs), digital signal processors (DSP), graphics processing unit (GPU), central processing unit (CPU), computer vision processor (CVP), or neural signal processor (NSP)) configured to perform the recited function through hardware, software, or a combination of hardware configured by software.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

One or more components, functional blocks, and modules described herein may include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

In one or more aspects, the operations described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

The operations of a method or process disclosed herein may be implemented in a processor-executable software module which may reside on a computer-readable medium and commercially made available as a computer program product as software. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc, where disks usually reproduce data magnetically and discs reproduce data optically with lasers. Combinations of the above should also be included within the scope of computer-readable media.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein but are to be accorded the widest scope consistent with this disclosure, the principles and the novel features disclosed herein.

Additionally, a person having ordinary skill in the art will readily appreciate, opposing terms such as “upper” and “lower,” or “front” and back,” or “top” and “bottom,” or “forward” and “backward,” or “left” and “right” are sometimes used for ease of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

As used herein, “based on” is intended to be interpreted in the inclusive sense, unless otherwise explicitly indicated. For example, “based on” may be used interchangeably with “based at least in part on,” “associated with,” “in association with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The term “substantially” is defined as largely, but not necessarily wholly, what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 5, 5, or 50 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A memory device comprising:
a memory array; and
control circuitry coupled to the memory array, the control circuitry configured to:
receive, from a memory controller, a write request to write data to the memory array, the data associated with an address of the memory array, the address corresponding to a row of storage elements of the memory array;
based on the row of storage elements including one or more storage elements associated with a defect, generate repair information associated with the data, wherein the repair information includes a copy of a particular subset of the data corresponding to a portion of the row of storage elements, the portion of the row of storage elements including the one or more storage elements associated with the defect;
store the data to the row of storage elements; and
store the repair information to the memory array.

2. The memory device of claim 1, wherein the data includes multiple different subsets including the particular subset, and wherein the repair information further includes a location tag indicating that, among the multiple different subsets, the particular subset is associated with the repair information.

3. The memory device of claim 1, wherein the repair information further includes a valid bit indicating that the copy is to replace the particular subset of the data.

4. The memory device of claim 1, wherein the control circuitry is further configured to:
receive a read request from a memory controller for the data;
based on the read request, read the repair information and a representation of the data from the memory array;
based on the repair information, replace the particular subset of the data with the copy to generate repaired data; and
provide the repaired data to the memory controller in connection with the read request.

5. The memory device of claim 1, wherein the data corresponds to a particular prefetch data unit of a group of prefetch data units, and wherein the repair information is reserved for the group of prefetch data units.

6. The memory device of claim 5, wherein the repair information further includes an identification tag indicating that, among the group of prefetch data units, the particular prefetch data unit is associated with the repair information.

7. The memory device of claim 5, wherein the control circuitry is further configured to:
receive a read request for at least one other prefetch data unit of the group of prefetch data units; and
read the repair information with the at least one other prefetch data unit irrespective of whether the repair information is related to the at least one other prefetch data unit.

8. The memory device of claim 1, wherein the memory array is configured to store multiple groups of prefetch data units, and wherein each group of the multiple groups of prefetch data units is associated with respective repair information.

9. The memory device of claim 1, wherein the control circuitry is further configured to:
receive a read request for the data from a memory controller;
receive the repair information and a representation of the data from the memory array; and
based on the repair information and the representation of the data, provide repaired data to the memory controller in accordance with the read request, wherein the repaired data corresponds the data.

10. The memory device of claim 1, wherein the repair information is associated with an in-memory repair scheme that is distinct from an error correction code (ECC) scheme of the memory device and that is distinct from a row or column replacement scheme of the memory device.

11. A method of operation of a memory device, the method comprising:
receiving, from a memory controller, a write request to write data to the memory device, the data associated with an address of the memory device, the address corresponding to a row of storage elements of the memory device;
based on the row of storage elements including one or more storage elements associated with a defect, generating repair information associated with the data, wherein the repair information includes a copy of a particular subset of the data corresponding to a portion of the row of storage elements, the portion of the row of storage elements including the one or more storage elements associated with the defect;
storing the data to the row of storage elements; and
storing the repair information to the memory device.

12. The method of claim 11, wherein the data includes multiple different subsets including the particular subset, and wherein the repair information further includes a location tag indicating that, among the multiple different subsets, the particular subset is associated with the repair information.

13. The method of claim 11, wherein the repair information further includes a valid bit indicating that the copy is to replace the particular subset of the data.

14. The method of claim 11, further comprising:
receiving a read request from a memory controller for the data;
based on the read request, reading the repair information and a representation of the data from the memory device;
based on the repair information, replacing the particular subset of the data with the copy to generate repaired data; and
providing the repaired data to the memory controller in connection with the read request.

15. The method of claim 11, wherein the data corresponds to a particular prefetch data unit of a group of prefetch data units, and wherein the repair information is reserved for the group of prefetch data units.

16. The method of claim 15, wherein the repair information further includes an identification tag indicating that, among the group of prefetch data units, the particular prefetch data unit is associated with the repair information.

17. The method of claim 15, further comprising:
receiving a read request for at least one other prefetch data unit of the group of prefetch data units; and
reading the repair information with the at least one other prefetch data unit irrespective of whether the repair information is related to the at least one other prefetch data unit.

18. The method of claim 11, wherein the memory device stores multiple groups of prefetch data units, and wherein each group of the multiple groups of prefetch data units is associated with respective repair information.

19. A non-transitory computer-readable medium storing instructions executable by one or more processors of a memory device to initiate, perform, or control operations, the operations comprising:
receiving, from a memory controller, a write request to write data to the memory device, the data associated with an address of the memory device, the address corresponding to a row of storage elements of the memory device;
based on the row of storage elements including one or more storage elements associated with a defect, generating repair information associated with the data, wherein the repair information includes a copy of a particular subset of the data corresponding to a portion of the row of storage elements, the portion of the row of storage elements including the one or more storage elements associated with the defect;
storing the data to the row of storage elements; and
storing the repair information to the memory device.

20. The non-transitory computer-readable medium of claim 19, wherein the data includes multiple different subsets including the particular subset, and wherein the repair information further includes a location tag indicating that, among the multiple different subsets, the particular subset is associated with the repair information.
